(19) United States
(12) Patent Application Publication
(10) Pub. No.: US 2013/0005052 A1
(43) Pub. Date: Jan. 3, 2013

(54) MAGNETIC TUNNEL JUNCTION WITH IRON DUSTING LAYER BETWEEN FREE LAYER AND TUNNEL BARRIER

(75) Inventors: Guohan Hu, Yorktown Heights, NY (US); Janusz J. Nowak, Highland Mills, NY (US); Philip L. Trouilloud, Norwood, NJ (US); Daniel C. Worledge, Cortlandt Manor, NY (US)

(73) Assignee: INTERNATIONAL BUSINESS MACHINES CORPORATION, Armonk, NY (US)

(21) Appl. No.: 13/604,236

(22) Filed: Sep. 5, 2012

Related U.S. Application Data
(63) Continuation of application No. 13/071,043, filed on Mar. 24, 2011.

(51) Int. Cl. H01L 43/12

(52) U.S. Cl. 438/3; 257/E43.006

(57) ABSTRACT

A magnetic tunnel junction (MTJ) for a magnetic random access memory (MRAM) includes a magnetic free layer having a variable magnetization direction; an iron (Fe) dusting layer formed on the free layer; an insulating tunnel barrier formed on the dusting layer; and a magnetic fixed layer having an invariable magnetization direction, disposed adjacent the tunnel barrier such that the tunnel barrier is located between the free layer and the fixed layer; wherein the free layer and the fixed layer have perpendicular magnetic anisotropy and are magnetically coupled through the tunnel barrier.

### CROSS-REFERENCE TO RELATED APPLICATION

This application is a continuation of U.S. patent application Ser. No. 13/071,043, filed Mar. 24, 2011, the disclosure of which is incorporated by reference herein in its entirety.

### BACKGROUND

This disclosure relates generally to the field of magnetoresistive random access memory (MRAM), and more specifically to materials for use in fabrication of magnetic tunnel junctions for spin torque transfer (STT) MRAM.

MRAM is a type of solid state, non-volatile memory that uses tunneling magnetoresistance (TMR) to store information. MRAM is made up of an electrically connected array of magnetoresistive memory elements, referred to as magnetic tunnel junctions (MTJs). Each MTJ includes a free layer and fixed layer that each include a layer of a magnetic material, and that are separated by a non-magnetic insulating tunnel barrier. The free layer has a variable magnetization direction, and the fixed layer has an invariable magnetization direction. An MTJ stores information by switching the magnetization state of the free layer. When the magnetization direction of the free layer is parallel to the magnetization direction of the fixed layer, the MTJ is in a low resistance state. Conversely, when the magnetization direction of the free layer is antiparallel to the magnetization direction of the fixed layer, the MTJ is in a high resistance state. The difference in resistance of the MTJ may be used to indicate a logical ‘1’ or ‘0’, thereby storing a bit of information. The TMR of an MTJ determines the difference in resistance between the high and low resistance states. A relatively high difference between the high and low resistance states facilitates read operations in the MRAM.

The magnetization direction of the free layer may be changed by a spin torque switched (STT) write method, in which a write current is applied in a direction perpendicular to the film plane of the magnetic films forming the MTJ. The write current has a tunneling magnetoresistive effect, so as to change (or reverse) the magnetization direction, or state, of the free layer of the MTJ. In STT magnetization reversal, the write current required for the magnetization reversal is determined by the current density. As the area of the surface in an MTJ on which the write current flows becomes smaller, the write current required for reversing the magnetization of the free layer of the MTJ becomes smaller. Therefore, if writing is performed with fixed current density, the necessary write current becomes smaller as the MTJ size becomes smaller. Inclusion of material layers that exhibit perpendicular anisotropy (PMA) in a MTJ also lowers the necessary write current density relative to MTJs having in-plane magnetic anisotropy, lowering the total necessary write current. However, MTJs that include PMA materials may not exhibit sufficient coercivity (H_{c}) to meet reliability and retention requirements for an MRAM made up of the PMA MTJs.

### BRIEF SUMMARY

In one aspect, a magnetic tunnel junction (MTJ) for a magnetic random access memory (MRAM) includes a magnetic free layer having a variable magnetization direction; an iron (Fe) dusting layer formed on the free layer; an insulating tunnel barrier formed on the dusting layer; and a magnetic fixed layer having an invariable magnetization direction, disposed adjacent the tunnel barrier such that the tunnel barrier is located between the free layer and the fixed layer; wherein the free layer and the fixed layer have perpendicular magnetic anisotropy.

In another aspect, a method of forming a magnetic tunnel junction (MTJ) for a magnetic random access memory (MRAM) includes forming a magnetic free layer having a variable magnetization direction; forming an iron (Fe) dusting layer over the free layer; forming a tunnel barrier comprising an insulating material over the Fe dusting layer; and forming a magnetic fixed layer having an invariable magnetization direction over the tunnel barrier, wherein the free layer and the fixed layer have perpendicular magnetic anisotropy.

Additional features are realized through the techniques of the present exemplary embodiment. Other embodiments are described in detail herein and are considered a part of what is claimed. For a better understanding of the features of the exemplary embodiment, refer to the description and to the drawings.

### BRIEF DESCRIPTION OF THE SEVERAL VIEWS OF THE DRAWINGS

Referring now to the drawings wherein like elements are numbered alike in the several FIGURES:

FIG. 1 is a cross sectional view illustrating an embodiment of an MTJ with an iron (Fe) dusting layer located between the free layer and the tunnel barrier.

FIG. 2 is a pair of graphs that illustrate the relationship between TMR and perpendicular field for a plurality of MTJs in an MRAM array with and without an Fe dusting layer between the free layer and the tunnel barrier.

FIG. 3 is a pair of graphs that illustrate the relationship between TMR and perpendicular field for a plurality of MTJs in an MRAM array with different compositions of the tunnel barrier.

FIG. 4 is a cross sectional view illustrating an embodiment of an MTJ with an Fe dusting layer located between the free layer and the tunnel barrier, and an interfacial layer located between the fixed layer and the tunnel barrier.

FIG. 5 is a cross sectional view illustrating an embodiment of an MTJ with an Fe dusting layer located between the free layer and the tunnel barrier, and a fixed layer comprising a synthetic anti-ferromagnetic (SAF) structure.

FIG. 6 is a cross sectional view illustrating an embodiment of an MTJ with an Fe dusting layer located between the free layer and the tunnel barrier, and a dipole layer.

### DETAILED DESCRIPTION

Embodiments of an MTJ with an iron (Fe) dusting layer located between the free layer and the tunnel barrier are provided, with exemplary embodiments being discussed below in detail. The addition of the Fe dusting layer increases the H_{c} in MTJs that include PMA materials. The Fe dusting layer may be relatively thin, for example, from about 0.2 angstroms (Å) to about 2 Å thick in some embodiments. A PMA MJT stack that includes an Fe dusting layer may be grown at room temperature, reducing manufacturing complexity for an MRAM comprising the PMA MTJs.

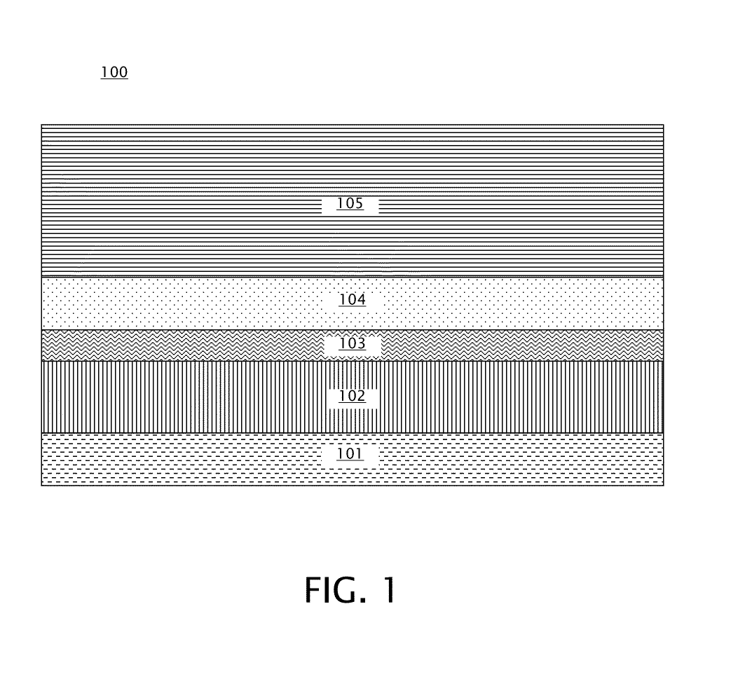

Referring initially to FIG. 1, there is shown a cross sectional view of an MTJ with an Fe dusting layer in accordance with an exemplary embodiment. As is shown, the MTJ 100 includes a seed layer 101 having free layer 102 grown thereon. The seed layer 101 may include, for example, tantalum (Ta) or tantalum magnesium (TaMg) in some embodiments. The free layer 102 may include cobalt-iron-boron (CoFeB), for example. An Fe dusting layer 103 is then formed on the free layer 102. Next, a tunnel barrier 104 is formed on the Fe dusting layer 103, wherein the tunnel barrier 104 may include a non-magnetic insulating material such as magnesium oxide (MgO), for example. Following the formation of the tunnel barrier 104, a fixed layer 105 is formed on top of the tunnel barrier 104. The fixed layer 105 may include, for example one or more interfacial layers, or spacers, and cobalt-platinum (Co|Pt) or cobalt-palladium (Co|Pd), in multilayers or a mixture, in various embodiments. The Fe dusting layer 103 may be formed by sputtering, as may various other layers that make up MTJ 100. The free layer 102 and the fixed layer 105 have perpendicular magnetic anisotropy.

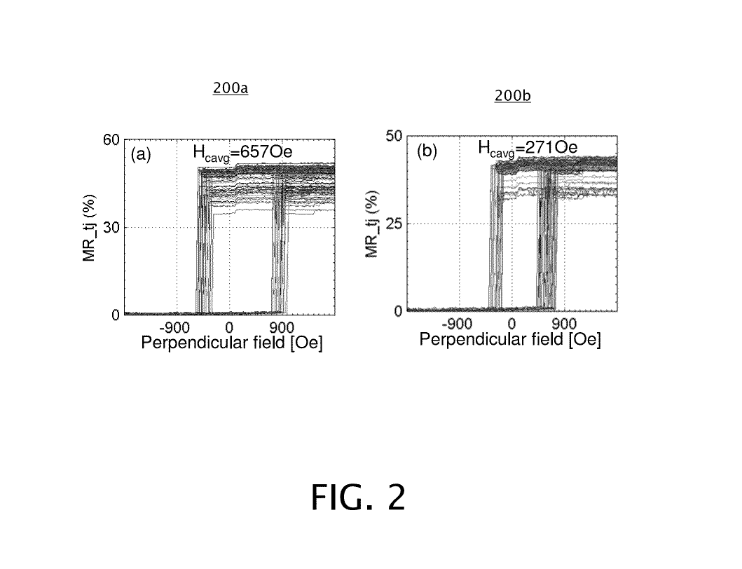

The presence of the Fe dusting layer 103 on top of a CoFeB free layer 102 significantly increases the H_{c} of the MTJ devices. For example, in an MTJ 100 with a free layer 102 made of 7CoFe₂₀B₂₀ and a dusting layer 103 that is about 0.4 Å thick, the H_{c} of a MTJ having a diameter of about 120 nanometer (nm) is about 600 to 700 Oersteds (Oe), compared to about 200 Oe for an MTJ with a 7CoFe₂₀B₂₀ free layer and no dusting layer, as illustrated by graphs 200a and 200b of FIG. 2. More specifically, graph 200a shows the relationship between TMR and the perpendicular field for 128 MTJs in a 4 kb MRAM array with a CoFeB free layer with an Fe dusting layer between the free layer and the tunnel barrier, while graph 200b shows the relationship between TMR and perpendicular field for 128 MTJs in a 4 kb MRAM array with a pure CoFeB free layer and no dusting layer.

For a given thickness of CoFeB in the free layer 102, as the Fe dusting layer is made thicker (e.g., greater than about 2 Å), the H_{c} of the MTJ eventually decreases because of the increase of total moment and weaker PMA. A relatively thick Fe dusting layer 103 may also increase the switching voltage (i.e., the voltage required to change the magnetization direction of the free layer, V_{c}) of the MTJ. Depending on the specific requirements for H_{c} (for retention) and V_{c} (for switching) for the MRAM comprising the MTJs, optimal CoFeB and Fe relative thicknesses may be selected. The thickness of the Fe dusting layer 103 may be from about 0.2 Å to about 2 Å thick in some embodiments.

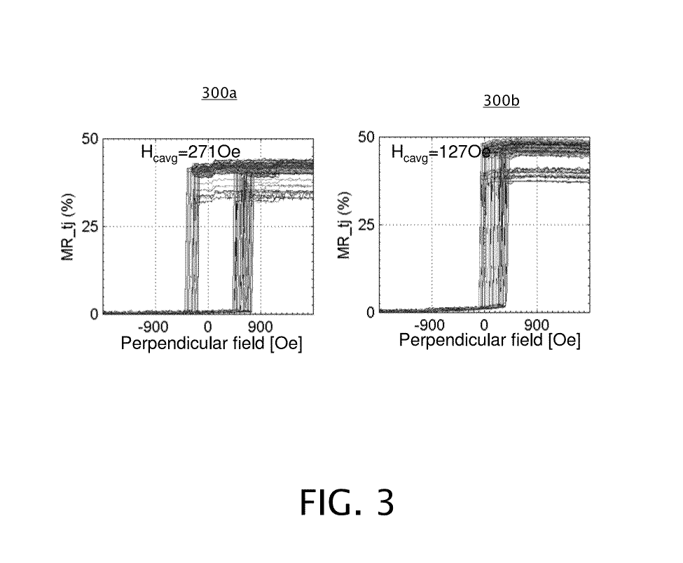

The MgO tunnel barrier 104 may be formed by radiofrequency (RF) sputtering in some embodiments. Alternatively, the MgO tunnel barrier 104 may be formed by oxidation (either natural or radical) of a layer of Mg in other embodiments. After oxidation, the MgO layer may then be capped with a second layer of Mg. The second layer of Mg may have a thickness of about 5 Å or less in some embodiments. The H_{c} of the free layer 102 may vary based on the method chosen to form the MgO tunnel barrier 104. For example, in the case of an MgO tunnel barrier 104 made by radical oxidation and capped with a second layer of Mg, the thickness of the second Mg layer may significantly impact the H_{c} of the free layer. For a first exemplary MTJ, when the barrier is made of 9 Å Mg|Radical Oxidation|3 Å Mg, an H_{c} of about 120 Oe is observed. For a second exemplary MTJ having the same free layer and fixed layer materials as the first exemplary MTJ, when the barrier is made of 9 Å Mg|Radical Oxidation|2 Å Mg, a H_{c} of about 270 Oe is observed. This is illustrated in graphs 300a and 300b of FIG. 3. More specifically, graph 300a shows the relationship between TMR and perpendicular field for a set of 128 MTJs in a 4 kb MRAM array, with each MTJ having a CoFeB free layer, a 9 Å Mg|Radical Oxidation|2Å Mg tunnel barrier. Graph 300b shows the relationship between TMR and perpendicular field for a set of 128 MTJs in a 4 kb MRAM array, with each MTJ having a CoFeB free layer, a 9 Å Mg|Radical Oxidation|3 Å Mg tunnel barrier.

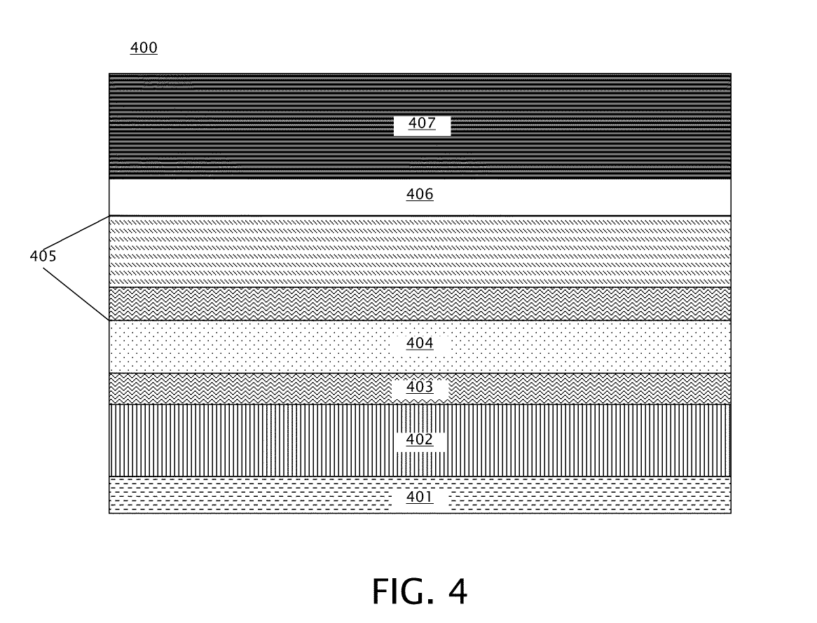

Referring now to FIG. 4, there is shown a cross sectional view of an MTJ 400, in accordance with another embodiment. Similar to the embodiment of FIG. 1, the MTJ includes a free layer 402 formed on a seed layer 401, a dusting layer 403 formed on the free layer 402, and a tunnel barrier 404 formed on the dusting layer 403. The various materials, thicknesses, and manner of forming the layers 401-404 may be similar to those shown in FIG. 1. Here, however, the MTJ 400 further includes an interfacial layer 405 formed on the tunnel barrier 404. In the embodiment depicted, the interfacial layer 405 includes a first layer of, for example, Fe, and a second layer of, for example, CoFeB. In an exemplary embodiment, the combined Fe/CoFeB interfacial layer 405 may have a total thickness of about 5 Å to about 15 Å.

As further depicted in FIG. 4, a spacer layer 406 is formed on the opposite side of the interfacial layer 405, with respect to the tunnel barrier 404. The spacer layer 406 may be formed a material such as Ta, for example, at an exemplary thickness of about 5 Å or less. Finally, a fixed layer 407 is formed on the spacer layer 406, at an opposite side of the spacer layer 406 with respect to the interfacial layer 405. The fixed layer 407 may include, for example, Co|Pd or Co|Pt multilayers. As is the case with the embodiment of FIG. 1, the free layer 402 and the fixed layer 407 have perpendicular magnetic anisotropy.

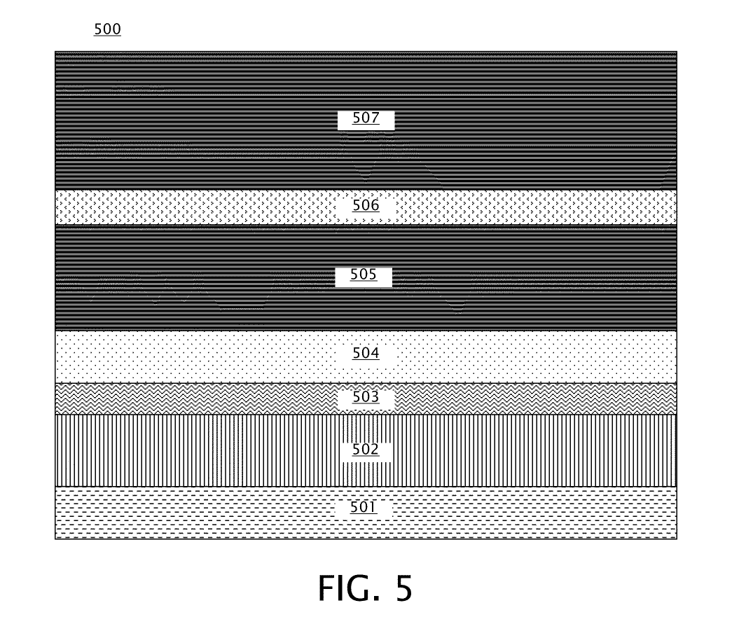

FIG. 5 is a cross sectional view illustrating another embodiment of a MTJ 500. Once again, the MTJ 500 includes, similar to the FIG. 1 and FIG. 4 embodiments, a free layer 502 formed on a seed layer 501, a dusting layer 503 formed on the free layer 502, and a tunnel barrier 504 formed on the dusting layer 503. In this particular embodiment, the MTJ 500 further includes a fixed layer shown collectively as layers 505-507 in FIG. 5, and which comprise a synthetic anti-ferromagnetic (SAF) structure. The SAF structure includes Co|Pd multilayers 505 and 507 that are coupled anti-ferromagnetically through a ruthenium (Ru) spacer 506 disposed therebetween. The SAF fixed layer structure 505-507 may reduce the offset field in the MTJ 500. Similar to the embodiments described above, the seed layer 501 may include Ta or TaMg while the free layer 502 may include CoFeB. The Fe dusting layer 503 may be from about 0.2 Å to about 2 Å thick in some embodiments. The tunnel barrier 504 may include a non-magnetic insulating material such as MgO, and may be formed by oxidation of Mg metal layers or RF sputtering. The Fe dusting layer 503 may be formed by sputtering, as may various other layers that make up MTJ 500. The free layer 502 and fixed layer 505-507 have perpendicular magnetic anisotropy.

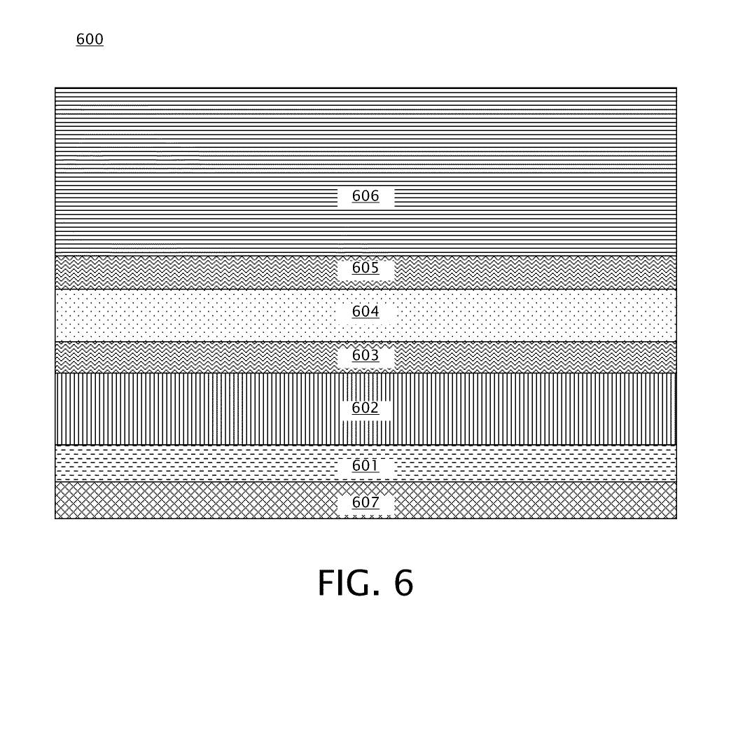

FIG. 6 is a cross sectional view illustrating still another embodiment of a MTJ 600. In this embodiment, however, a dipole layer below the free layer is used to reduce the offset field of the MTJ, in contrast to the SAF fixed layer structure in the embodiment of FIG. 5. As shown in FIG. 6, the MTJ 600 includes, similar to the above described embodiments, a free layer 602 formed on a seed layer 601, a dusting layer 603 formed on the free layer 602, and a tunnel barrier 604 formed on the dusting layer 503. In addition, an interfacial layer 605 is formed on the tunnel barrier 604, and a fixed layer 606 is formed on the interfacial layer 605. As is the case with previous embodiments, the free layer 602 may include CoFeB, and have a thickness from about 5 Å to about 15 Å, while the Fe dusting layer 603 may be from about 0.2 Å to about 2 Å thick. The tunnel barrier 604 may include a non-magnetic insulating material such as MgO, and may be formed by oxidation of Mg metal layers or RF sputtering. Further, the interfacial layer 405 may include, for example, both Fe and CoFeB. As further shown in FIG. 6, a dipole layer 607 is formed beneath the free layer 602 to reduce the offset field of the MTJ 600. The dipole layer 607 may include, for example, cobalt-nickel (Co|Ni), Co|Pt or Co|Pd multilayers, which exhibit PMA. As is the case with other embodiments, the free layer 602 and the fixed layer 606 have perpendicular magnetic anisotropy.

It should be appreciated that the exemplary MTJ embodiments 100, 400, 500, and 600 discussed above with respect to FIGS. 1 and 4-6 are shown for illustrative purposes only, and it is contemplated that other suitable MTJ structures may be formed in which an Fe dusting layer is disposed between a free layer and a tunnel barrier so as to provide sufficient coercivity (H_{c}) to meet reliability and retention requirements for an MRAM made up of the PMA MTJs.

The technical effects and benefits of exemplary embodiments include increased coercivity and magnetoresistance in a MTJ through addition of the Fe dusting layer.

The terminology used herein is for the purpose of describing particular embodiments only and is not intended to be limiting of the invention. As used herein, the singular forms “a”, “an”, and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

1. A method of forming a magnetic tunnel junction (MTJ) for a magnetic random access memory (MRAM), the method comprising:
forming a magnetic free layer having a variable magnetization direction;
forming an iron (Fe) dusting layer over the free layer;
forming a tunnel barrier comprising an insulating material over the Fe dusting layer; and
forming a magnetic fixed layer having an invariable magnetization direction over the tunnel barrier, wherein the free layer and the fixed layer have perpendicular magnetic anisotropy and are magnetically coupled through the tunnel barrier.

2. The method of claim 1, wherein forming the tunnel barrier comprises one of radical oxidation, natural oxidation, and radiofrequency (RF) sputtering.

3. The method of claim 2, wherein the tunnel barrier comprises magnesium oxide (MgO) that is formed by radical oxidation of a first layer of magnesium (Mg), and is capped by a second layer of Mg formed on the radically oxidized MgO.

4. The method of claim 1, wherein the Fe dusting layer is formed by sputtering.

5. The method of claim 1, wherein the free layer comprises cobalt-iron-boron (CoFeB), and wherein forming the free layer comprises growing the free layer on a seed layer comprising one of tantalum (Ta) and tantalum magnesium (TaMg).

6. The method of claim 1, further comprising forming an interfacial layer between the tunnel barrier and the fixed layer, the interfacial layer comprising a layer of Fe and a layer of CoFeB.

7. The method of claim 1, further comprising forming a tantalum spacer between the interfacial layer and the fixed layer.

8. The method of claim 1, further comprising forming a dipole layer adjacent the free layer, wherein the free layer is located between the dipole layer and the tunnel barrier.
